(19) United States
(12) Patent Application Publication
(10) Pub. No.: US 2024/0297162 A1
(43) Pub. Date: Sep. 5, 2024

(54) LED LIGHT BEAD

(71) Applicant: Zhongshan Mulinsen Electronics Co., Ltd., Zhongshan (CN)

(72) Inventors: Baoqing PI, Zhongshan (CN); Xuezhao HE, Zhongshan (CN); Lei ZHU, Zhongshan (CN)

(73) Assignee: Zhongshan Mulinsen Electronics Co., Ltd., Zhongshan (CN)

(21) Appl. No.: 18/663,754

(22) Filed: May 14, 2024

(30) Foreign Application Priority Data
Feb. 8, 2024 (CN) 202410177195.0

(51) Int. Cl. H01L 25/075; H01L 33/48; H01L 33/50; H01L 33/56; H01L 33/62

(52) U.S. Cl. CPC H01L 25/0753; H01L 33/486; H01L 33/50; H01L 33/56; H01L 33/62; H01L 2933/0091

(57) ABSTRACT

A new type of LED light, related to a technical field of LED, including a cup body. The cup body includes a first light-emitting assembly, a second light-emitting assembly and a third light-emitting assembly. The first light-emitting assembly is used to emit green light, the second light-emitting assembly is used to emit blue light, and the third light-emitting assembly is used to emit blue light. A first phosphor layer is provided on the second light-emitting assembly or the third light-emitting assembly, so that the blue light emitted by the second light-emitting assembly or the third light-emitting assembly is transformed into red light after passing through the first phosphor layer. The present disclosure emits red light through a combination of blue light and a phosphor layer, replacing traditional red lights, improving the performance of the new type of LED light and reducing costs.

### CROSS-REFERENCE TO RELATED APPLICATIONS

The application claims priority to Chinese patent application No. 202410177195.0, filed on Feb. 8, 2024, the entire contents of which are incorporated herein by reference.

### TECHNICAL FIELD

The present disclosure relates to the technical field of LED (Light Emitting Diode), and in particular to a new LED light bead.

### BACKGROUND

With LED lights' advantages of wide color gamut, high brightness, long life, energy saving and environmental protection, and real-time color controllability, in particularly, LED backlights of wide color gamut make the screens of TVs, mobile phones, tablets and other electronic products to display more vivid color and higher color accuracy. At present, LED light beads emit a variety of colored lights by using the combination of RGB (Red, Green, Blue), generally including red light bead, blue light bead and green light bead. Among the existing RGB LED light beads, red light beads are mostly made from gallium arsenide, which is limited in export. Therefore, it is difficult and costly to produce red light beads, and their power is limited. Furthermore, as the temperature rises in use, the brightness of red light beads significantly decreases. All these disadvantages are due to the limitation that existing red light beads are directly made from gallium arsenide materials.

### SUMMARY

The present disclosure is to provide a new LED light bead, which emits red light, orange light or yellow light through a combination of blue light and a phosphor layer, replacing traditional red light beads, thereby improving the performance of the LED light beads and reducing a cost.

Therefore, the present disclosure provides the new LED light bead, which includes a cup body, while the cup body is provided on a first light-emitting assembly, a second light-emitting assembly and a third light-emitting assembly. The first light-emitting assembly is used to emit green light, the second light-emitting assembly to emit blue light, and the third light-emitting assembly to emit a third color light;

The first light-emitting assembly at least includes a first light-emitting chip, the second light-emitting assembly includes a second light-emitting chip for emitting blue light, and the third light-emitting assembly includes a third light-emitting chip for emitting blue light. The second light-emitting chip or the third light-emitting chip is also provided with a first phosphor layer, so that the blue light emitted by the second light-emitting chip or the third light-emitting chip is transformed into the third color light after passing through the first phosphor layer;

Wherein, the third color light includes any of red light, orange light, and yellow light.

The new LED light bead as mentioned above, the first phosphor layer is sprayed or spot-coated on the outer peripheral surface of the second light-emitting assembly or the third light-emitting assembly.

The new LED light bead as mentioned above, the thickness of the first phosphor layer is 1 to 250 μm.

The new LED light bead as mentioned above, the second light-emitting assembly includes a plurality of second light-emitting chips connected in series.

The new LED light bead as mentioned above, the first light-emitting assembly includes a plurality of first light-emitting chips connected in series.

The new LED light bead as mentioned above, the third light-emitting assembly includes a plurality of third light-emitting chips connected in series.

The new LED light bead as mentioned above, the cup body is also packaged with an encapsulation layer covering the first light-emitting assembly, the second light-emitting assembly and the third light-emitting assembly.

The new LED light bead as mentioned above, the encapsulation layer is a transparent layer, which is formed by any one or more selected from epoxy resin, silicone resin, and silicone.

The new LED light bead as mentioned above, the encapsulation layer is a diffused powder layer.

With the implementation of the embodiment, the present disclosure has following beneficial effects.

The present disclosure provides the new LED light bead. Through adding the first phosphor layer to the second light-emitting assembly or the third light-emitting assembly that emits blue light, the emitted blue light is transformed into the third color light after passing through the first phosphor layer. Light color can be configured with red, orange or yellow according to requirements, making it equivalent to a traditional RGB LED light bead. Furthermore, compared with the traditional red light bead, the new LED light bead that is not limited by the material of red light bead, and can achieve higher power to meet brightness requirements and reduce the overall cost.

The new LED light bead of the present disclosure, with the light-emitting assemblies through adopting a single chip or a combination of multiple chips connected in series, an overall power of the light-emitting assemblies is increased to meet brightness requirements.

### BRIEF DESCRIPTION OF DRAWINGS

In order to more clearly illustrate the technical solutions in the embodiments of the present disclosure, drawings that need to be used in the embodiments are briefly described below, and it is obvious that the drawings in following description are merely some embodiments of the present disclosure, and for those who skilled in the art, other drawings may be obtained based on these drawings without exerting creative efforts.

FIG. 1 is a schematic diagram of the new LED light bead in a first embodiment of the present disclosure.

FIG. 2 is a schematic diagram of the new LED light bead in a second embodiment of the present disclosure.

FIG. 3 is a schematic diagram of the cross section of the new LED light bead.

### DETAILED DESCRIPTION OF THE EMBODIMENTS

The technical solutions of the present disclosure are described more clearly and completely below in combined with accompanying drawings of embodiments of the present disclosure. It should be known that the embodiments in following description are merely some embodiments of the present disclosure instead of all embodiments. On the basis of the embodiments of the present disclosure, all embodiments obtained by those who skilled in the art without creative work are included in the protection of the present disclosure.

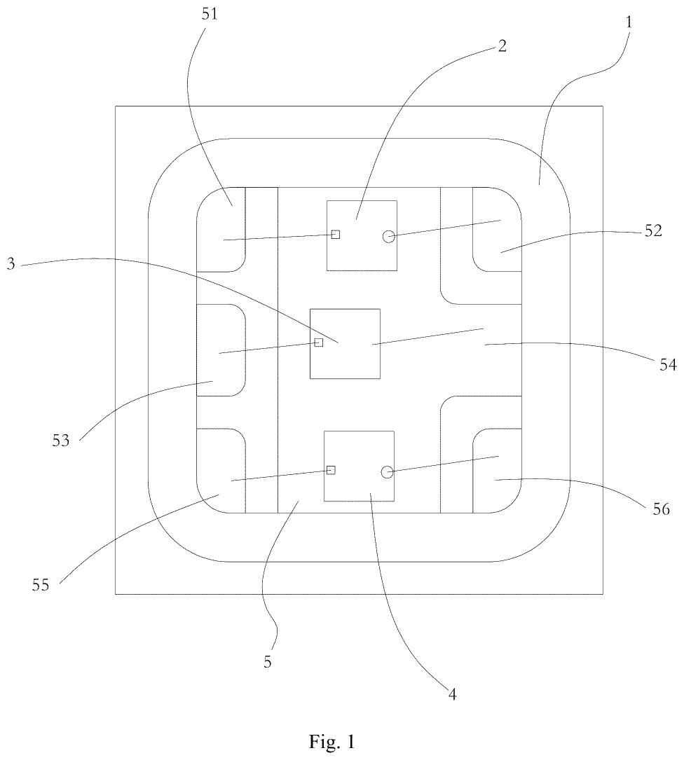

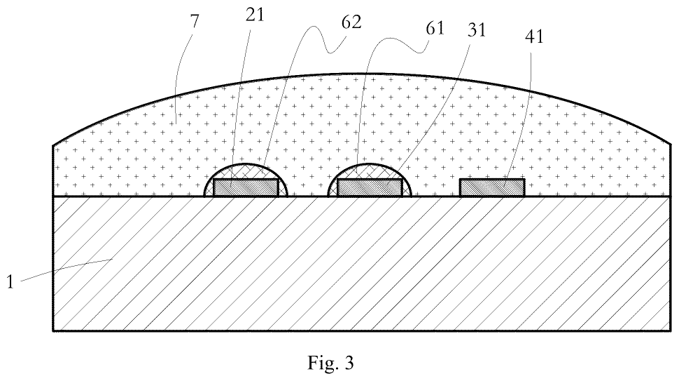

As shown in FIGS. 1 and 3, an embodiment of the present disclosure provides a new LED light bead, including a cup body 1. The cup body 1 is equipped with a first light-emitting assembly 2, a second light-emitting assembly 3 and a third light-emitting assembly 4. The first light-emitting assembly 2 is used to emit green light, the second light-emitting assembly 3 is used to emit blue light, and the third light-emitting assembly 4 is used to emit a third color light; the first light-emitting assembly 2 at least includes a first light-emitting chip 21, the second light-emitting assembly 3 includes a second light-emitting chip 31 for emitting blue light, and the third light-emitting assembly 4 includes a third light-emitting chip 41 for emitting blue light; the second light-emitting chip 31 or the third light-emitting chip 41 is also provided with a first phosphor layer 61, so that the blue light emitted by the second light-emitting chip 31 or the third light-emitting chip 41 is transformed into the third color light after passing through the first phosphor layer 61; wherein, the third color light includes any of red light, orange light, and yellow light. The present disclosure provides the new LED light bead, the cup body is used as a connection support for the first light-emitting assembly 2, the second light-emitting assembly 3, and the third light-emitting assembly 4 for encapsulation in this solution; the first phosphor layer 61 is added to the second light-emitting assembly 3 or the third light-emitting assembly 4 that emits blue light, so that the emitted blue light is transformed into the third color light after passing through the first phosphor layer 61. Light color can be configured with red, orange or yellow according to requirements, making it equivalent to a traditional RGB LED light bead. Furthermore, compared with traditional red light beads, the new LED light bead that is not limited by the material of red light bead, and can achieve higher power to meet brightness requirements and reduce the overall cost.

Certainly, the green light emitted by the first light-emitting assembly 2 in this embodiment can also be emitted by combining blue light with a phosphor layer. Specifically, the first light-emitting chip 21 is used to emit blue light, and the first light-emitting chip 21 is also provided with a second phosphor layer 62, so that the blue light emitted by the first light-emitting chip 21 can be transformed into green light after passing through the second phosphor layer 62. The present disclosure only needs a green phosphor layer cooperating with a blue light-emitting chip that is cheaper than a green light-emitting chip, thereby further reducing the overall cost of RGB LED light beads.

Furthermore, in the embodiments of the present disclosure, the light-emitting assemblies used to emit blue light can be made from gallium nitride and sapphire, whose cost is much lower than that that of gallium arsenide. Moreover, red light can be emitted by a combination of the first phosphor layer 61 and the second light-emitting assembly 3 or the third light-emitting assembly 4 that emit blue light, which is less affected by the temperature of the environment during operation and the brightness decrease due to high temperature is relieved. In the embodiments of the present disclosure, red light can be emitted by the combination of the first phosphor layer 61 and the second light-emitting assembly 3 or the third light-emitting assembly 4 that emit blue light. The red light can be adjusted into light of different wavelength ranges according to the parameters of the first phosphor layer 61. Generally speaking, the wavelength of red light emitted in this combination is between 50 and 1000 nm. In production, only phosphor of different wavelengths is needed to make phosphor layers of different wavelengths, according to the preset parameters of LED light beads.

In the embodiments of the present disclosure, the first phosphor layer 61 is made from a combination of red phosphor and AB glue. During production, the first phosphor layer 61 is sprayed or spot-coated on the outer peripheral surface of the second light-emitting assembly 3 or the third light-emitting assembly 4. Its production is simple, which is beneficial to reducing the cost of the overall LED light beads. Moreover, depending on the usage requirements, the thickness of the first phosphor layer 61 in the embodiment of the present disclosure is 1 to 250 μm.

Specifically, in the embodiments of the present invention, the second light-emitting assembly 3 is located between the first light-emitting assembly 2 and the third light-emitting assembly 4, and the first phosphor layer 61 is provided on the second light-emitting assembly 3.

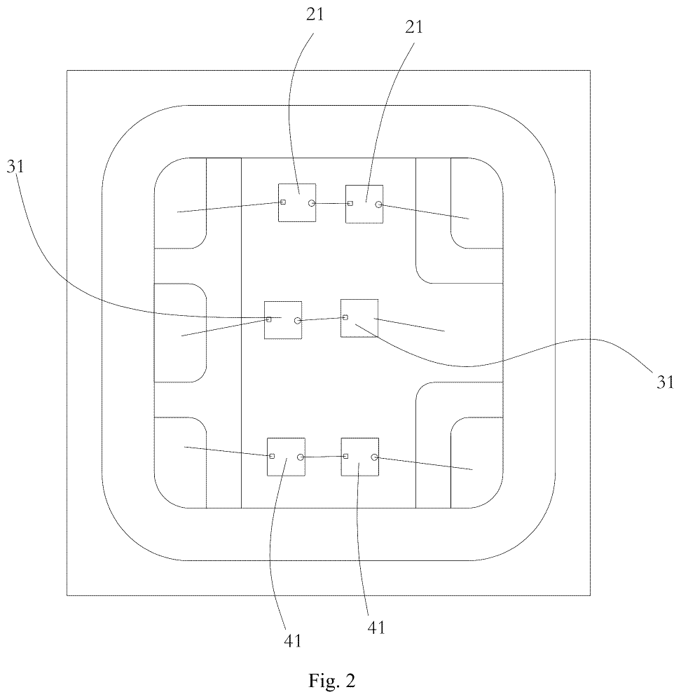

As shown in FIGS. 1 and 2, in these embodiments, the light-emitting assemblies can use a single chip or a combination of multiple chips connected in series, an overall power of the light-emitting assemblies is increased and to meet the brightness requirements. Specifically, the second light-emitting assembly 3 includes a plurality of second light-emitting chips 31 connected in series, the first light-emitting assembly 2 includes a plurality of first light-emitting chips 21 connected in series, and the third light-emitting assembly 4 includes a plurality of the third light-emitting chips 41 connected in series. Light of different brightness can be provided according to requirements and in a way of efficiency, stability and easiness to control, enriching its application in lighting, display and other fields.

Taking the second light-emitting assembly 3 as an example, an operating voltage of the second light-emitting assembly 3 is 3.0V to 100.0V, such as 3.0V, 6.0V, 9.0V, 18.0V, 12.0V, 18.0V, 27.0V, 36.0V, 54.0V, 100.0V; the operating voltage can be achieved by a light-emitting chip, or by multiple light-emitting chips connected in series. For example, the operating voltage of 9.0V can be achieved by using three 3.0V chips connected in series.

In order to further improve the effect of displayed brightness, the cup body 1 in these embodiments also packaged with an encapsulation layer 7 covering the first light-emitting assembly 2, the second light-emitting assembly 3 and the third light-emitting assembly 4.

The first embodiment of the encapsulation layer 7 is: the encapsulation layer 7 is a transparent layer, which is formed by any one or more selected from epoxy resin, silicone resin, and silicone.

The second embodiment of the encapsulation layer 7 is: the encapsulation layer 7 is a diffused powder layer. The diffused powder layer is used to make the new LED light bead emitting light of more uniform brightness. The materials of a diffused powder in this embodiment are:

A glue: B glue: CY-3000=100%: 100%: 10%. The diffused powder has multiple advantages in use, such as uniformly modifying light spots, turning a color of light circle into consistent, high product purity, high temperature resistance, less impact on brightness decrease, and universally usable in SMD (Surface-mount Device) LED, direct plug-in LED.

In the embodiments of the present invention, the cup body 1 is provided with a base 5, a first positive electrode pin 51 and a first negative electrode pin 52 are arranged on opposite sides of the base 5. The first light-emitting assembly 2 is attached on the base 5 and are electrically connected to the first positive electrode pin 51 and the first negative electrode pin 52 respectively.

A second positive electrode pin 53 and a second negative electrode pin 54 are arranged on opposite sides of the base 5; the second light-emitting assembly 3 is attached to the base 5 and is electrically connected to the second positive electrode pin 53 and the second negative electrode pin 54.

A third positive electrode pin 55 and a third negative electrode pin 56 are also provided on opposite sides of the base 5. The second positive electrode pin 53 is provided between the first positive electrode pin 51 and the third positive electrode pin 55, and the second negative electrode pin 54 is provided between the first negative electrode pin 52 and the third negative electrode pin 56; the third light-emitting assembly 4 is attached to the base 5, and are electrically connected to the third positive electrode pin 55 and the third negative electrode pin 56 respectively.

The present disclosure provides the new LED light bead, through adding the first phosphor layer to 61 the second light-emitting assembly 3 or the third light-emitting assembly 4 that emits blue light, the emitted blue light is transformed into red light after being passing through the first phosphor layer 61, making it equivalent to a traditional RGB LED light bead. Furthermore, compared with the traditional red LED light bead, the present disclosure is not limited by the material of red light beads, and can achieve higher power to meet brightness requirements and reduce the overall cost. It should be understood that the terms like “first” and “second” are used in the present disclosure to describe various information, but the information should not be limited to these terms, and these terms are only used to distinguish the same type of information from each other. For example, in the case of without departing from the scope of the present disclosure, a “first” information may also be called a “second” information, and similarly, the “second” information may also be called the “first” information. In addition, the terms “center”, “upper”, “lower”, “left”, “right”, “vertical”, “horizontal”, “inner”, “outer”, etc. indicate an orientation or positional relationship based on the drawings. The orientation or positional relationship shown is only to facilitate the description of the present invention and simplify the description, and does not indicate or imply that the device or element referred to must have a specific orientation, or be constructed and operated in a specific orientation, and therefore cannot be understood as limiting the scope of the present disclosure.

The above are preferred embodiments of the present disclosure. It should be pointed out that for those of ordinary skill in the art, several improvements and deformations can be made without departing from the principles of the present invention. These improvements and deformations are also regarded as the protection scope of the present disclosure.

What is claimed is:

1. A LED light bead, comprising a cup body, wherein a first light-emitting assembly, a second light-emitting assembly and a third light-emitting assembly are provided on the cup body; the first light-emitting assembly is used to emit green light, the second light-emitting assembly is used to emit blue light, and the third light-emitting assembly is used to emit third color light;
the first light-emitting assembly includes at least a first light-emitting chip, the second light-emitting assembly includes a second light-emitting chip for emitting blue light, and the third light-emitting assembly includes a third light-emitting chip for emitting blue light; the second light-emitting chip or the third light-emitting chip is also provided with a first phosphor layer, so that the blue light emitted by the second light-emitting chip or the third light-emitting chip is transformed into the third color light after passing through the first phosphor layer;
wherein, the third color light includes any of red light, orange light, and yellow light.

2. The LED light bead according to claim 1, wherein the first light-emitting chip is used to emit blue light, and the first light-emitting chip is also provided with a second phosphor layer, so that the blue light emitted by the first light-emitting chip is transformed into green light after passing through the second phosphor layer.

3. The LED light bead according to claim 2, wherein the first phosphor layer is sprayed or spot-coated on the outer peripheral surface of the second light-emitting assembly or the third light-emitting assembly.

4. The LED light bead according to claim 3, wherein the thickness of the first phosphor layer is 1 to 250 μm.

5. The LED light bead according to claim 1, wherein the second light-emitting assembly includes a plurality of second light-emitting chips connected in series.

6. The LED light bead according to claim 5, wherein the first light-emitting assembly includes a plurality of first light-emitting chips connected in series.

7. The LED light bead according to claim 5, wherein the third light-emitting assembly includes a plurality of third light-emitting chips connected in series.

8. The LED light bead according to claim 1, wherein the cup body is also packaged with an encapsulation layer covering the first light-emitting assembly, the second light-emitting assembly and the third light-emitting assembly.

9. The LED light bead according to claim 8, wherein the encapsulation layer is a transparent layer, which is formed by any one or more selected from epoxy resin, silicone resin, and silicone.

10. The LED light bead according to claim 8, wherein the encapsulation layer is a diffused powder layer.

11. The LED light bead according to claim 1, wherein the cup body is provided with a base, a first positive electrode pin and a first negative electrode pin are arranged on opposite sides of the base, the first light-emitting assembly is attached on the base and are electrically connected to the first positive electrode pin and the first negative electrode pin respectively;
a second positive electrode pin and a second negative electrode pin are arranged on opposite sides of the base; the second light-emitting assembly is attached to the base and is electrically connected to the second positive electrode pin and the second negative electrode pin.

12. The LED light bead according to claim 11, wherein a third positive electrode pin and a third negative electrode pin are provided on opposite sides of the base, the second positive electrode pin is provided between the first positive electrode pin and the third positive electrode pin, and the second negative electrode pin is provided between the first negative electrode pin and the third negative electrode pin;
the third light-emitting assembly is attached to the base, and are electrically connected to the third positive electrode pin and the third negative electrode pin respectively.
